(19) United States
(12) Patent Application Publication
(10) Pub. No.: US 2026/0324293 A1
(43) Pub. Date: Oct. 15, 2026

(54) GAUSSIAN BIT CIRCUIT WITH MULTIPLE MTJ CELLS

(71) Applicant: Taiwan Semiconductor Manufacturing Company, Ltd., Hsinchu (TW)

(72) Inventors: Yu-Sheng Chen, Taoyuan City (TW); Yi-Hsuan Chen, Taoyuan City (TW); Yen-Liang Chu, Hsinchu (TW); Yi Ching Ong, Hsinchu (TW); Kuo-Ching Huang, Hsinchu City (TW)

(21) Appl. No.: 19/307,473

(22) Filed: Aug. 22, 2025

Related U.S. Application Data
(60) Provisional application No. 63/788,193, filed on Apr. 14, 2025.

(51) Int. Cl. H10N 50/10; G11C 11/16; H10B 61/00; H10N 50/80

(52) U.S. Cl. CPC H10N 50/10; G11C 11/161; G11C 11/1675; H10B 61/22; H10N 50/80

(57) ABSTRACT

In some embodiments, an integrated circuit is provided. The integrated circuit includes a transistor arranged along a semiconductor substrate, an interconnect structure overlying the transistor, and a memory cell overlying the transistor and coupled to the transistor by the interconnect structure. The interconnect structure includes a plurality of conductive lines respectively arranged in a plurality of conductive interconnect layers, and a plurality of conductive vias. The memory cell includes a plurality of resistance changing elements that are coupled to one another by the interconnect structure, and are arrange vertically between a first conductive interconnect layer and a second conductive interconnect layer of the plurality of conductive interconnect layers, the second conductive interconnect layer overlying and being adjacent to the first conductive interconnect layer.

### REFERENCE TO RELATED APPLICATION

This Application claims the benefit of U.S. Provisional Application number 63/788,193, filed on Apr. 14, 2025, the contents of which are hereby incorporated by reference in their entirety.

### BACKGROUND

Conventional p-bits typically use binary variables (e.g., 0 or 1) to solve problems based on mathematical models such as the Ising model, aiming to identify an optimal solution. However, many real-world problems require continuous variables (e.g., those following a Gaussian distribution) rather than discrete binary values. To address this, Gaussian bits, which can represent continuous states, are sometimes used for solving practical problems. Gaussian bit circuits generally suffer from large area requirements and complex metal routings for multiple input and output signals. Therefore, improved Gaussian bit circuits that occupy less area and utilize simpler routing structures are desirable to enhance scalability and integration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a circuit diagram of an exemplary Gaussian bit circuit having a transistor and a plurality of resistance changing elements according to a first embodiment.

FIG. 1B illustrates a cross-sectional view of a resistance changing element in the exemplary Gaussian bit circuit in FIG. 1A according to some embodiments.

FIG. 1C illustrates multiple states that can be represented by outputs of the exemplary Gaussian bit circuit in FIG. 1A according to the first embodiment.

FIG. 1D illustrates a cross-sectional view of the exemplary Gaussian bit circuit in FIG. 1A according to the first embodiment.

FIG. 1E illustrates a layout view of the exemplary Gaussian bit circuit in FIG. 1D according to the first embodiment.

FIG. 1F illustrates a program circuit that can be used to program the plurality of resistance changing elements in FIG. 1A according to some embodiments.

FIG. 2A illustrates a circuit diagram of another exemplary Gaussian bit circuit having a transistor and a plurality of resistance changing elements according to the first embodiment.

FIG. 2B illustrates a three-dimensional (3D) view of the exemplary Gaussian bit circuit in FIG. 2A according to the first embodiment.

FIG. 2C illustrates a layout view of the exemplary Gaussian bit circuit in FIG. 2B according to the first embodiment.

FIG. 3A illustrates a circuit diagram of an exemplary Gaussian bit circuit having a transistor and a plurality of resistance changing elements according to a second embodiment.

FIG. 3B illustrates a cross-sectional view of the exemplary Gaussian bit circuit in FIG. 3A according to the second embodiment.

FIG. 3C illustrates a layout view of the exemplary Gaussian bit circuit in FIG. 3B according to the second embodiment.

FIG. 4A illustrates a circuit diagram of another exemplary Gaussian bit circuit having a transistor and a plurality of resistance changing elements according to a second embodiment.

FIG. 4B illustrates a cross-sectional view of the exemplary Gaussian bit circuit in FIG. 4A according to the second embodiment.

FIG. 4C illustrates a layout view of the exemplary Gaussian bit circuit in FIG. 4B according to the second embodiment.

FIG. 5A illustrates a circuit diagram of an exemplary Gaussian bit circuit having a transistor and a plurality of resistance changing elements according to a third embodiment.

FIG. 5B illustrates a cross-sectional view of the exemplary Gaussian bit circuit in FIG. 5A according to the third embodiment.

FIG. 5C illustrates a layout view of the exemplary Gaussian bit circuit in FIG. 5B according to the third embodiment.

FIG. 6A illustrates a circuit diagram of another exemplary Gaussian bit circuit having a transistor and a plurality of resistance changing elements according to a third embodiment.

FIG. 6B illustrates a cross-sectional view of the exemplary Gaussian bit circuit in FIG. 6A according to the third embodiment.

FIG. 6C illustrates a layout view of the exemplary Gaussian bit circuit in FIG. 6B according to the third embodiment.

FIG. 7A illustrates a circuit diagram of an exemplary Gaussian bit circuit having a transistor and a plurality of resistance changing elements according to a fourth embodiment.

FIG. 7B illustrates a cross-sectional view of the Gaussian bit circuit in FIG. 7A according to the fourth embodiment.

FIG. 7C illustrates a layout view of the Gaussian bit circuit in FIG. 7B according to the fourth embodiment.

FIG. 8A illustrates a circuit diagram of a Gaussian bit circuit having a transistor and a plurality of resistance changing elements according to a fourth embodiment.

FIG. 8B illustrates a cross-sectional view of the Gaussian bit circuit in FIG. 8A according to the fourth embodiment.

FIG. 8C illustrates a layout view of the Gaussian bit circuit in FIG. 8B according to the fourth embodiment.

FIGS. 9A-9G are a series of cross-sectional views of intermediate semiconductor structures that illustrate some exemplary steps of a method for manufacturing a Gaussian bit circuit having a transistor and a plurality of resistance changing elements in FIGS. 1A, 1D and 1E according to some embodiments.

FIG. 10 illustrates a flow diagram of a method for manufacturing a Gaussian bit circuit having a transistor and a plurality of resistance changing elements in FIGS. 1A, 1D and 1E according to some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Gaussian bit circuits are typically used in computing paradigms where randomness, probability, or statistical distribution are fundamental. Gaussian bit circuits can be used for example in Stochastic computing, probabilistic inference engines, hardware accelerators for Machine Learning (ML), security and cryptography, and neuromorphic computing, etc. A conventional Gaussian bit circuit typically includes multiple unit cells, each unit cell containing one transistor (1T) and one magnetic tunnel junction (1MTJ) and thus being in a “1T1MTJ” configuration. Such a Gaussian bit circuit can ideally represent 2^{N} distinct states, where N is a total number of the “1T1MTJ” unit cells. In an example, where N=4, the Gaussian bit includes four “1T1MTJ” unit cells, and can ideally represent sixteen (2⁴) states. However, such a Gaussian bit circuit may disadvantageously occupy a large area, and may have complicated metal line routing for inputting and outputting signals.

The present disclosure relates to various designs, configurations, and implementations of Gaussian bit circuits. In some embodiments, a Gaussian bit circuit includes a first power node for receiving one of a supply voltage and a reference voltage, a second power node for receiving another one of the supply voltage and the reference voltage, an input node for receiving an input signal, an output node for providing an output signal, a transistor that includes a first terminal that is coupled to the output node, a second terminal that is coupled to the second power node, and a control terminal that is coupled to the input node, and a plurality of resistance changing elements that are coupled between the first power node and the output node in parallel, in series, or in a combination of series and parallel. In some embodiments, the resistance changing elements are magnetic tunnel junctions (MTJs). As such, the Gaussian bit circuit occupies a smaller area, and allows for simplified metal line routings for inputting and outputting signals, thereby advantageously enhancing integration efficiency and scalability.

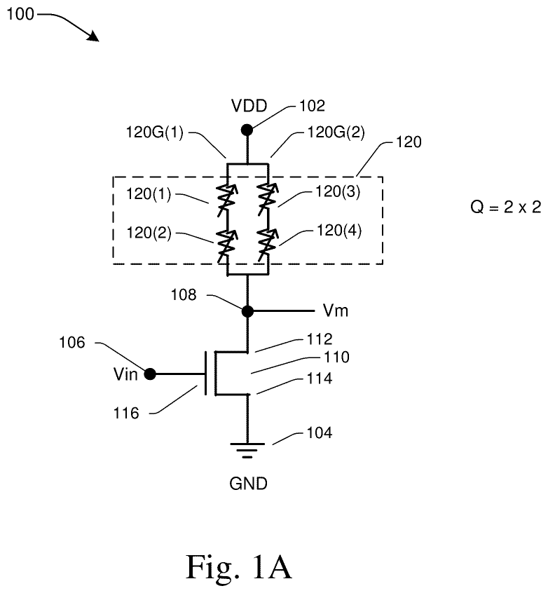

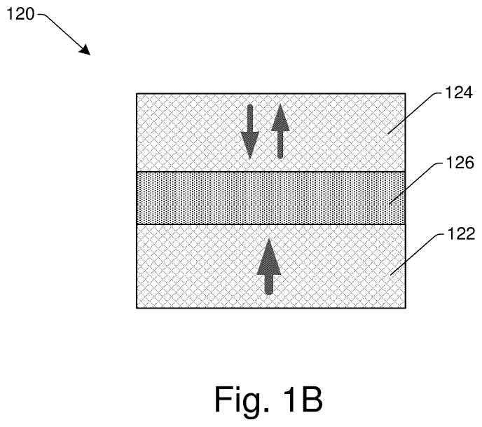

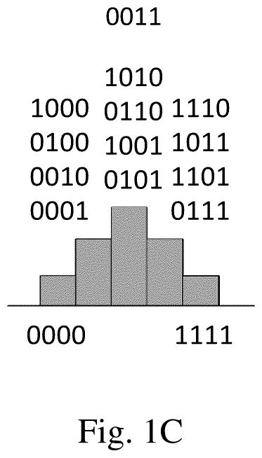

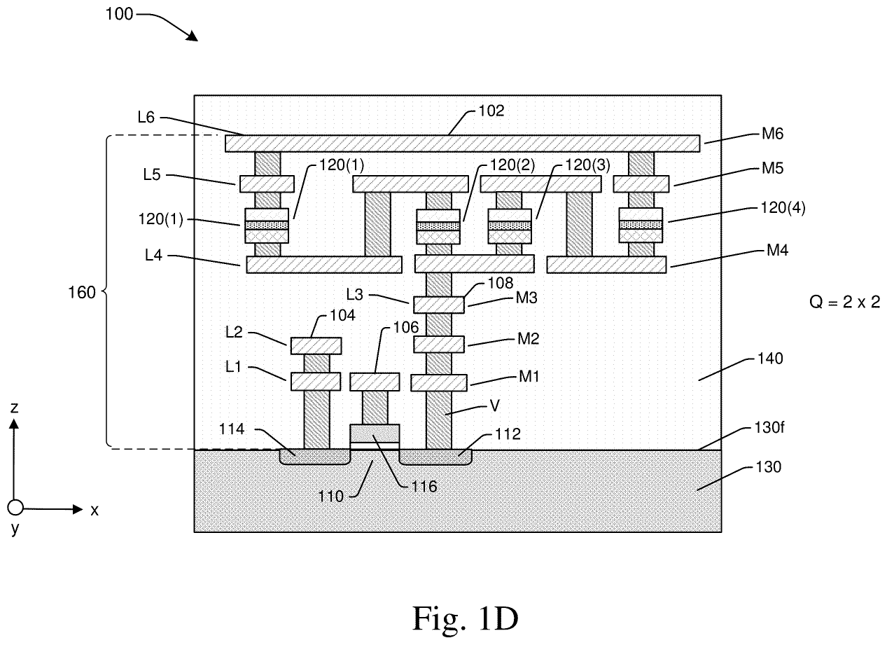

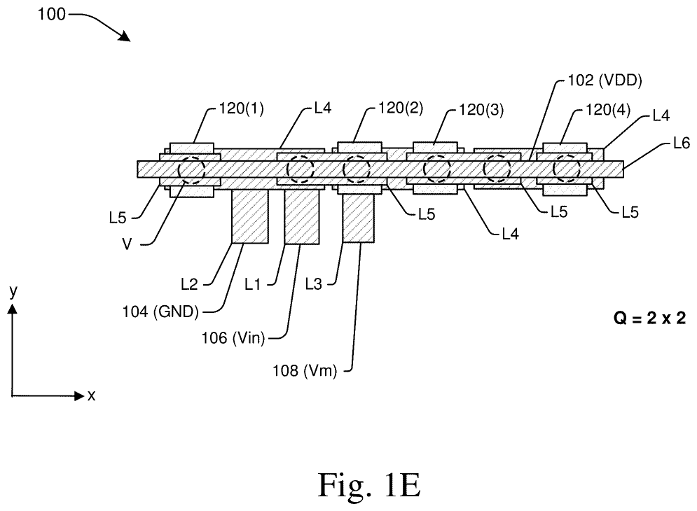

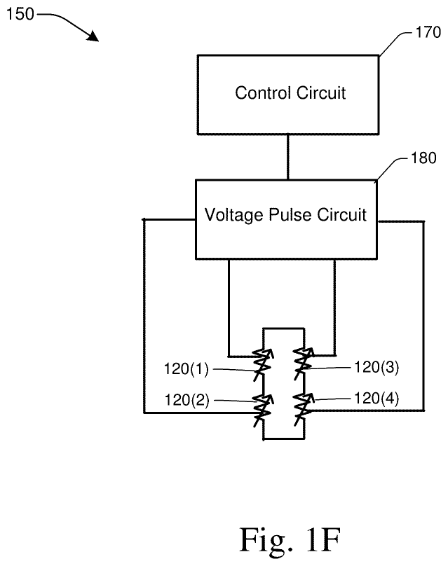

FIG. 1A illustrates a circuit diagram of an exemplary Gaussian bit circuit 100 having a transistor 110 and a plurality of resistance changing elements 120 according to a first embodiment of the present disclosure. The exemplary Gaussian bit circuit 100 includes a first power node 102 for receiving one of a supply voltage (VDD) and a reference voltage (GND), a second power node 104 for receiving another of the supply voltage (VDD) and the reference voltage (GND), an input node 106 for receiving an input signal (Vin), and an output node 108 for providing an output signal (Vm). In some embodiments, the first power node 102 is for receiving the supply voltage (VDD), and the second power node 104 is for receiving the reference voltage (GND) (as shown in FIG. 1A), and in other embodiments, the first power node 102 is for receiving the reference voltage (GND), and the second power node 104 is for receiving the supply voltage (VDD) (not shown).

In some embodiments, the exemplary Gaussian bit circuit 100 further includes a transistor 110 and a plurality (Q) of resistance changing elements 120 (such as 120(1)-120(Q)) incorporated with the transistor 110. In some embodiments, the transistor 110 includes a first terminal (e.g., a source terminal) 112 coupled to the output node 108, a second terminal (e.g., a drain terminal) 114 coupled to the second power node 104, and a control terminal (e.g., a gate terminal) 116 coupled to the input node 106. In some embodiments, the control terminal 116 may be implemented in different transistor architectures, such as Fin Field-Effect Transistor (FinFET), Gate-All-Around (GAA) FET, or Complementary FET (CFET). The control terminal 116 may include a gate dielectric layer comprising a high-k dielectric material (e.g., HfO₂, k>10) and a gate electrode comprising a work function metal (e.g., TiN, TaN, Ru, Mo, or W). In some embodiments, the plurality (Q) of resistance changing elements 120 (such as 120(1)-120(Q), e.g., Q=4) are coupled between the first power node 102 and the output node 108 in a combination of series and parallel configurations (as shown in FIG. 1A). In some embodiments, the plurality (Q) of resistance changing elements 120 (such as 120(1)-120(Q)) in FIG. 1A are a plurality of magneto-resistive random-access memory (MRAM) elements that each comprise a magnetic tunnel junction (MTJ). In various embodiments, the plurality (Q) of resistance changing elements 120 (such as 120(1)-120(Q) may each be or comprise a phase-change random-access memory (PCRAM) element, a resistive random access memory (RRAM) element, a metal-cation RRAM element, or the like. In other embodiments, the plurality of resistance changing elements in FIG. 1A are selected from temperature dependent resistors, light dependent resistors, strain dependent resistors, voltage dependent resistors, humidity dependent resistors, or piezoelectric resistors.

In some embodiments, the plurality (Q) of resistance changing elements 120 (such as 120(1)-120(Q)) are divided into a number (n) of element groups 120G (120G(1)-120G(n)) that are coupled in parallel between the first power node 102 and the output node 108, and each element group 120G (such as 120G(1)) includes a number (m) of resistance changing elements 120 (such as 120(1)-120(m)) coupled in series, and thus Q=n×m. Such a configuration of the Gaussian bit circuit 100 can be referred to as a “1T +(n×m) MTJ” configuration.

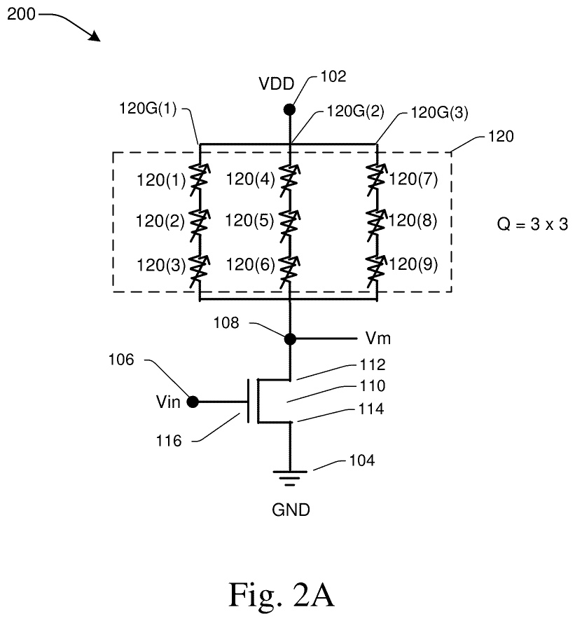

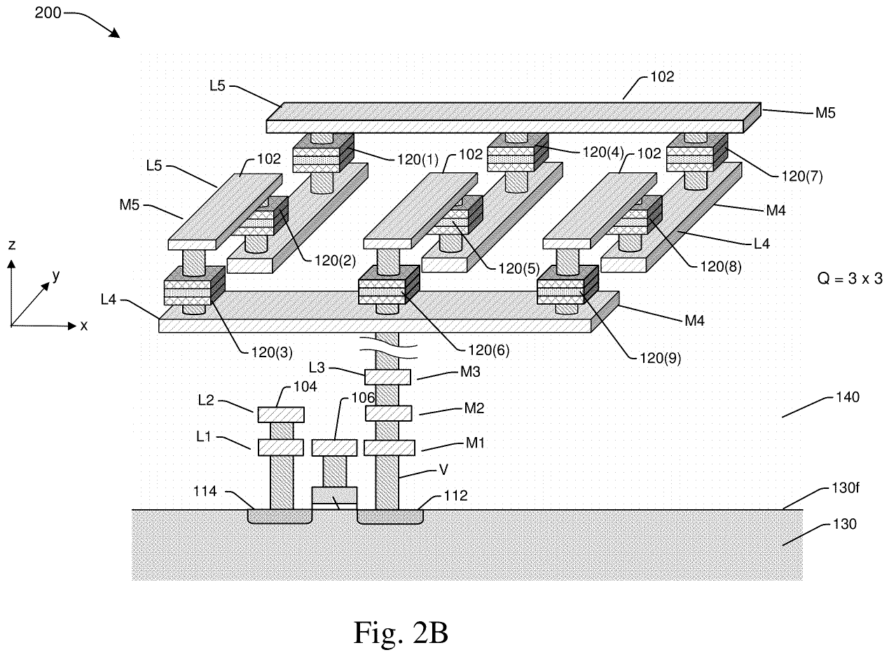

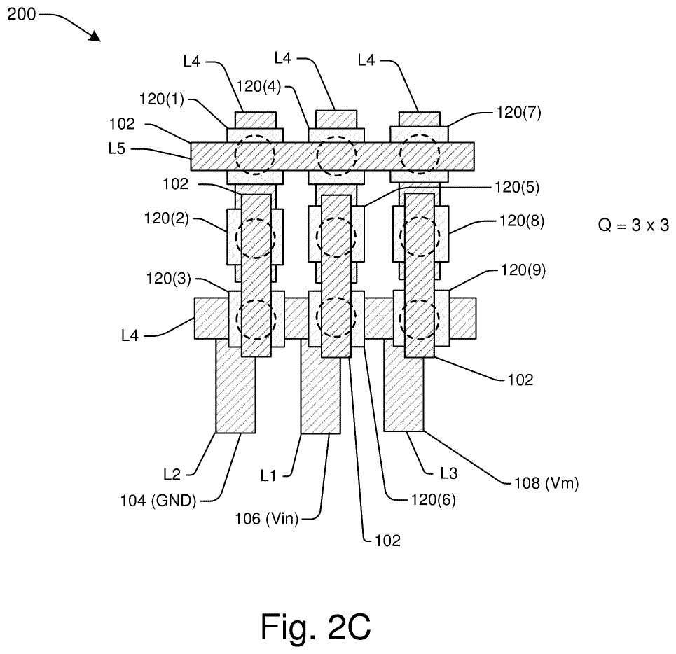

In some embodiments, in the “1T+(n×m) MTJ” configuration, the number (n) of element groups 120G is equal to the number (m) of resistance changing elements 120 in each element group 120G, that is n=m. As shown in for example FIG. 1A, n=m=2, thus Q=n×m=n×n=2×2. As shown in for example FIG. 2A, n=m=3, thus Q=n×m=n×n=3×3. In some embodiments, the number n can be in a range from 2 to 10.

In other embodiments, in the “1T+(n×m) MTJ” configuration, not shown in the figures, the number (n) of element groups 120G is different from the number (m) of resistance changing elements 120 (120(1)-120(m)) in each element group 120G (such as 120G(1)), that is n≠m, n>1, m>1, thus Q=n×m (such as 3×2, 4×2, 4×3, 5×2, 5×3, 5×4, 6×2, 6×3, 6 ×4, 6×5, etc.) (not shown in the figures). In some embodiments, the number n can be in a range from 2 to 10, and the number m can be in a range from 2 to 10.

In some embodiments, as shown in FIG. 1A, for example, a memory cell includes a plurality of resistance changing elements 120 (such as 120(1)-120(4)) that are coupled between a single input node 106 and a single output node 108. The memory cell is configured to have a number of discrete data states greater than a number (e.g., four) of resistance changing elements 120 in the plurality of resistance changing elements 120, and the number of resistance changing elements is equal to or greater than two.

FIG. 1B illustrates a cross-sectional view of an exemplary MTJ 120 (such as 120(1)) of the plurality (Q) of MTJs 120 (such as 120(1)-120(Q)) in the exemplary Gaussian bit circuit 100 in FIG. 1A according to some embodiments. In some embodiments, an MTJ 120 (such as 120(1)) includes a pinned magnetic layer 122, a free magnetic layer 124, and a tunnel barrier layer 126 that vertically separates the pinned magnetic layer 122 and the free magnetic layer 124. A magnetic orientation of the pinned magnetic layer 122 is static (i.e., fixed), while a magnetic orientation of the free magnetic layer 124 is capable of switching between a parallel configuration and an anti-parallel configuration with respect to that of the pinned magnetic layer 122. The parallel configuration provides for a low resistance state that digitally stores data as a first data state (such as a logic “0”). The anti-parallel configuration provides for a high resistance state that digitally stores data as a second data state (such as a logic “1”).

FIG. 1C illustrates multiple states that can be represented by an output (or output signal) Vm of the exemplary Gaussian bit circuit 100 in FIG. 1A according to some embodiments. In some embodiments, each resistance changing element (such as 120(1)) of the resistance changing elements 120 in FIG. 1A is a magnetic tunnel junction (MTJ). Each of the MTJs 120 (such as 120(1)-120(Q)) can be programmed to represent any one of logic “0” and logic “1”. Referring to FIG. 1B, the resistance of a MTJ 120 (e.g., 120(1)) can be changed by manipulating the magnetization of its free magnetic layer 124 through applying an external voltage pulse for example. By altering the magnetization orientation of the free magnetic layer 124, the MTJ 120 (e.g., 120(1)) can switch between a low-resistance (parallel alignment) state (representing a logic “0”) and a high-resistance (antiparallel alignment) state (representing a logic “1”). The MTJs 120 in FIG. 1A totally includes four MTJs 120(1)-120(4) arranged in a configuration of “1T +(2×2) MTJ”.

Referring to FIG. 1F that illustrates a program circuit 150 that can be used to program the plurality of resistance changing elements in FIG. 1A according to some embodiments. The program circuit 150 includes a control circuit 170 and a voltage pulse circuit 180 that is coupled to the control circuit 170 and also coupled to each of the MTJs 120 (such as 120(1)-120(4)) in FIG. 1A. The control circuit 170 is programmed to control voltage pulse circuit 180 to selectively supply voltage pulses to the MTJs 120 in FIG. 1A to set each of the MTJs 120 in either a low-resistance state (representing a logic “0”) or a high-resistance state (representing a logic “1”).

In a first embodiment, the output signal Vm of the exemplary Gaussian bit circuit 100 in FIG. 1A has five voltage magnitudes. When the four MTJs 120(1)-120(4) are programed to represent “0000”, the output signal Vm has a first voltage magnitude. When the four MTJs 120(1)-120(4) are programed to represent any one of “1000”, “0100”, “0010” and “0001”, the output signal Vm has a second voltage magnitude. When the four MTJs 120(1)-120(4) are programed to represent any one of “1010”, “0110”, “1001” and “0101”, the output signal Vm has a third voltage magnitude. When the four MTJs 120(1)-120(4) are programed to represent any one of “1110”, “1011”, “1101” and “0111”, the output signal Vm has a fourth voltage magnitude. When the four MTJs 120(1)-120(4) are programed to represent “1111”, the output signal Vm has a fifth voltage magnitude.

In a second embodiment, the output signal Vm of the exemplary Gaussian bit circuit 100 in FIG. 1A has six voltage magnitudes that include the aforesaid first to fifth voltage magnitudes in the first embodiment, and a sixth voltage magnitude. When the four MTJs 120(1)-120(4) are programed to represent any one of “1100” and “0011”, the output signal Vm has the additional sixth voltage magnitude.

FIG. 1D illustrates a cross-sectional view of the exemplary Gaussian bit circuit 100 in FIG. 1A according to the first embodiment. FIG. 1E illustrates a layout view of the exemplary Gaussian bit circuit 100 in FIG. 1D according to the first embodiment.

As shown in FIG. 1D, in some embodiments, a transistor 110 is formed along a frontside 130f of a semiconductor substrate 130, and a conductive interconnect structure 160 is formed in a dielectric layer 140 arranged over the frontside 130f of a semiconductor substrate 130. In some embodiments, the conductive interconnect structure 160 includes a plurality of conductive lines L (such as L1, L2, L3, L4, L5, L6, etc.) respectively arranged in a plurality of conductive interconnect layers M (such as M1, M2, M3, M4, M5, M6, etc.), and a plurality of conductive vias V for selectively connecting some of the plurality of conductive lines L.

As shown in FIG. 1D, in some embodiments, the exemplary Gaussian bit circuit 100 further includes a first power node 102 for receiving one of a supply voltage (VDD), a second power node 104 for receiving a reference voltage (GND), an input node 106 for receiving an input signal (Vin), an output node 108 for providing an output signal (Vm), the transistor 110 and a plurality (Q) of MTJs 120 (such as four MTJs 120(1)-120(4)) coupled to the transistor 110 by the conductive interconnect structure 160. In some embodiments, the transistor 110 includes a first terminal (such as a source terminal) 112 that is coupled to the output node 108 (such as by lines such as L1, L2, L3 and multiple vias V), a second terminal (such as a drain terminal) 114 that is coupled to the second power node 104 (such as by lines such as L1, L2, and vias), and a control terminal (such as a gate terminal) 116 that is coupled to the input node 106 (such as by L1 and a via V).

Referring to FIGS. 1A and 1D, the four MTJs 120(1)-120(4) are coupled between the first power node 102 and the output node 108 in a combination of parallel and series configurations by the conductive interconnect structure 160. In some embodiments, the four MTJs 120 (such as 120(1)-120(4)) are divided into two MTJ groups (or branches) 120G, such as a first MTJ group 120G(1) and a second MTJ group 120G(2), which are coupled in parallel by the conductive interconnect structure 160. The first MTJ group 120G(1) includes a first MTJ 120(1) and a second MTJ 120(2) that are coupled in series by the conductive interconnect structure 160, and the second MTJ group 120G(2) includes a third MTJ 120(3) and a fourth MTJ 120(3) that are coupled in series by the conductive interconnect structure 160. In some embodiments, a MTJ 120 (such as 120(1)) is vertically arranged in a back-end-of-the-line (BEOL) over frontside 130f of a semiconductor substrate 130 and vertically between a bottom electrode (such as conductive line L4 in conductive layer M4) and a top electrode (such as conductive line L5 in conductive layer M5). In some embodiments, the MTJs 120 (such as 120(1)-120(Q)) are arranged in a one-dimensional array, while in other embodiments, the MTJs 120 (such as 120(1)-120(Q)) are arranged in a two-dimensional array.

In some embodiments, as shown in FIGS. 1D and 1E, all the plurality (Q) of MTJs 120 (such as 120(1)-120(Q)) are coplanar. For example, all of the MTJs 120 (such as 120(1) 120(Q)) are located between the i^{th} conductive layer (Mi) (for example, but not limited to, the fourth conductive layer (M4)) and the (i+1)^{th} conductive layer (M(i+1)) (for example, but not limited to, the fifth metal layer (M5)), where i≥1. In other embodiments, not shown, the MTJs 120 (such as 120(1)-120(Q)) are alternatively non-coplanar. For example, some of the MTJs 120 (such as 120(1)-120(Q)) may be located for example between the fourth metal layer (M4) and the fifth metal layer (M5), and other ones of the MTJs 120 (such as 120(1)-120(Q)) may be located for example between the second metal layer (M2) and the third metal layer (M3).

In some embodiments, as shown in FIGS. 1D and 1E, the conductive lines L (such as L4 and L5) for connecting the MTJs 120 (such as 120(1)-120(Q)) together are formed in two the conductive layers M (such as M4 and M5), the conductive line L (such as L6) for transmitting the supply voltage (VDD) is formed in a conductive layer (such as M6), the conductive line (such as L2) for transmitting the reference voltage (GND) is formed in a conductive layer (such as M2), the conductive line (such as L1) for transmitting the input signal (Vin) is formed in a conductive layer (such as M1), the conductive line (such as L3) for transmitting the output signal (Vm) is formed in a conductive layer (such as M3).

Since one transistor 110, one input node 106, and one output node 108 are predominantly required, the Gaussian bit circuit 100 occupies a smaller area, and has simplified metal line routing for the input signal (Vin) and the output signal (Vm), thereby advantageously enhancing integration efficiency and scalability.

FIG. 2A illustrates a circuit diagram of another exemplary Gaussian bit circuit 200 having a transistor 110 and a plurality of resistance changing elements 120 according to the first embodiment. FIG. 2B illustrates a three-dimensional (3D) view of the exemplary Gaussian bit circuit 200 in FIG. 2A according to the first embodiment. FIG. 2C illustrates a layout view of the exemplary Gaussian bit circuit 200 in FIG. 2B according to the first embodiment. Similar to the Gaussian bit circuit 100 in FIG. 1A, the Gaussian bit circuit 200 in FIG. 2A has a configuration “1T +(n×n) MTJs”, where n=3.

As shown in FIGS. 2A, 2B and 2C, the exemplary Gaussian bit circuit 200 includes a first power node 102 for receiving one of a supply voltage (VDD) and a reference voltage (GND), a second power node 104 for receiving another of the supply voltage (VDD) and the reference voltage (GND), an input node 106 for receiving an input signal (Vin), and an output node 108 for providing an output signal (Vm), a transistor 110, and a plurality (Q) of resistance changing elements 120 (such as 120(1)-120(9)) coupled to the transistor 110. In some embodiments, the transistor 110 includes a first terminal (e.g., a source terminal) 112 that is coupled to the output node 108, a second terminal (e.g., a drain terminal) 114 that is coupled to the second power node 104, and a control terminal (such as a gate terminal) 116 that is coupled to the input node 106. In some embodiments, the plurality (Q) of resistance changing elements 120 (such as 120(1)-120(9)) are a plurality of magnetic tunnel junctions (MTJs).

Referring to FIGS. 2A and 2B, the nine MTJs 120(1)-120(9) are coupled between the first power node 102 and the output node 108 in a combination of parallel and series configurations by the conductive interconnect structure 160. In some embodiments, the nine MTJs 120 (such as 120(1)-120(9)) are divided into three MTJ groups (or branches) 120G, such as a first MTJ group 120G(1), a second MTJ group 120G(2), and a third MTJ group 120G(3), which are coupled in parallel by the conductive interconnect structure 160. The first MTJ group 120G(1) includes a first MTJ 120(1), a second MTJ 120(2), and a third MTJ 120(3) that are coupled in series by the conductive interconnect structure 160. The second MTJ group 120G(2) includes a fourth MTJ 120(4), a fifth MTJ 120(5), and a sixth MTJ 120(6) that are coupled in series by the conductive interconnect structure 160. The third MTJ group 120G(3) includes a seventh MTJ 120(7), an eighth MTJ 120(8), and a ninth MTJ 120(9) that are coupled in series by the conductive interconnect structure 160. Although FIG. 1A shows Q=2×2 (n=2) and FIG. 2A shows Q=3×3 (n=3), n is not limited to 2 or 3. In some embodiments, Q=n×n, and n can be any integer that is greater than 1, for example n=2, 3, 4, 5, 6, 7, 8, 9, or 10.

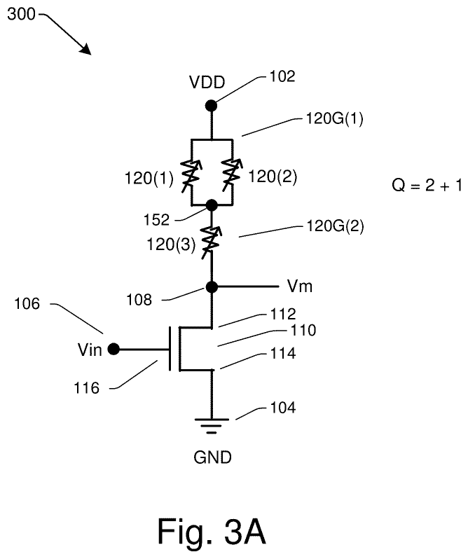

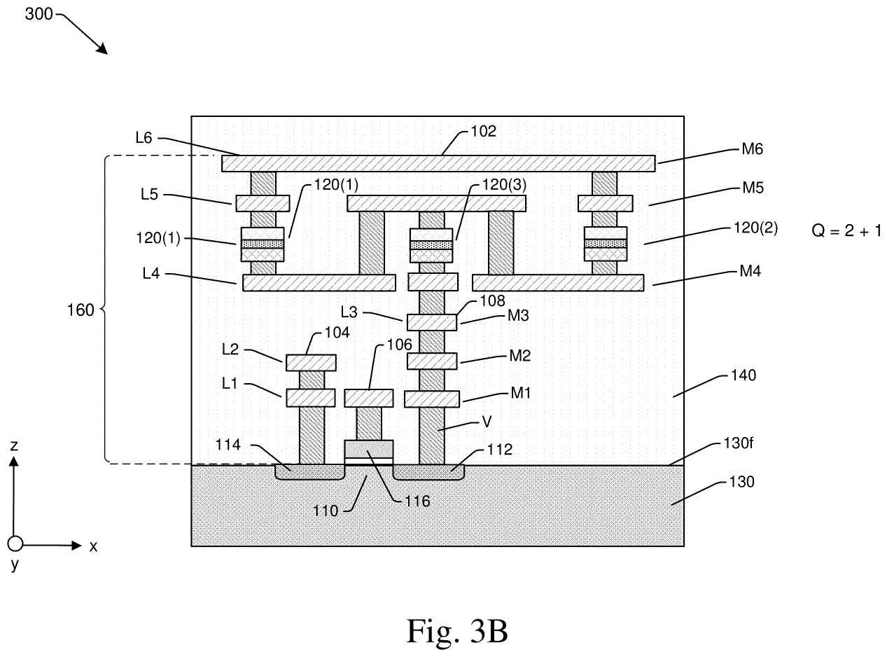

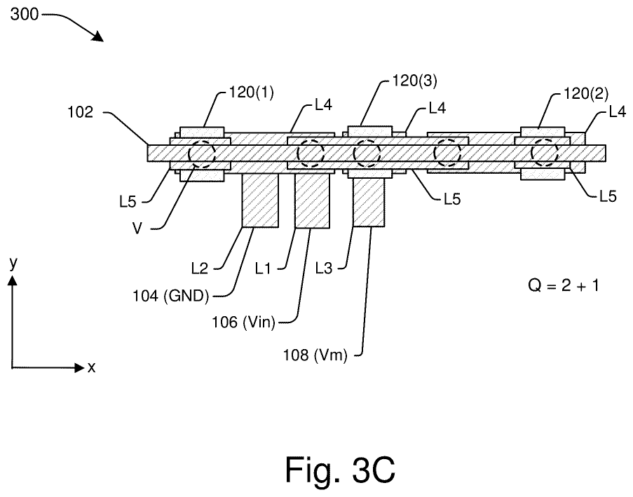

FIG. 3A illustrates a circuit diagram of an exemplary Gaussian bit circuit 300 having a transistor 110 and a plurality of resistance changing elements 120 according to a second embodiment. FIG. 3B illustrates a cross-sectional view of the exemplary Gaussian bit circuit 300 in FIG. 3A according to the second embodiment. FIG. 3C illustrates a layout view of the exemplary Gaussian bit circuit 300 in FIG. 3B according to the second embodiment.

The implementation in the second embodiment as shown in FIG. 3A is similar to that of the first embodiment (for example as shown in FIGS. 1A and 2A), but has some differences. In the first embodiment, a Gaussian bit circuit 100 includes, among other things, a transistor 110 and a plurality (Q) of MTJs 120 (such as 120(1)-120(Q)) in a configuration “1T+(n×m) MTJ”, where Q=n×m, n=m (e.g., in FIG. 1A), or n≠m (not shown)). In the second embodiment, e.g., in FIG. 3A, a Gaussian bit circuit 200 includes, among other things, a transistor 110 and a plurality (Q) of MTJs 120 (such as 120(1)-120(Q)) in a different configuration “1T+(n+m) MTJ”, where Q=n+m, n≥1, m≥1, and n≠m. For example, in the second embodiments, Q can be 2+1, 2+3, 2+4, 3+1, 3+2, 3+4, 4+1, 4+2, 4+3, etc.

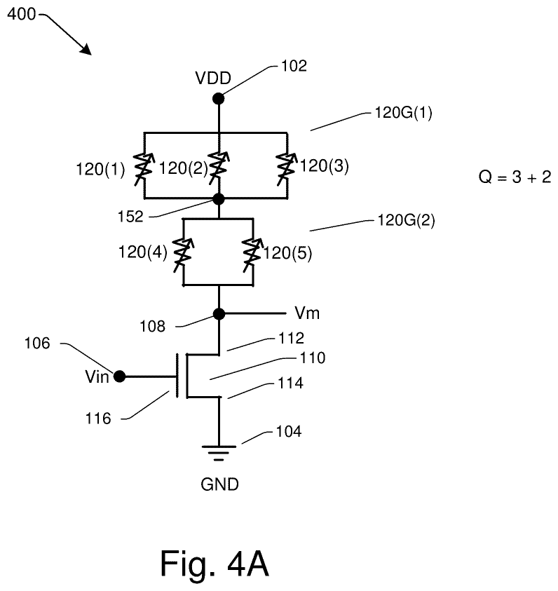

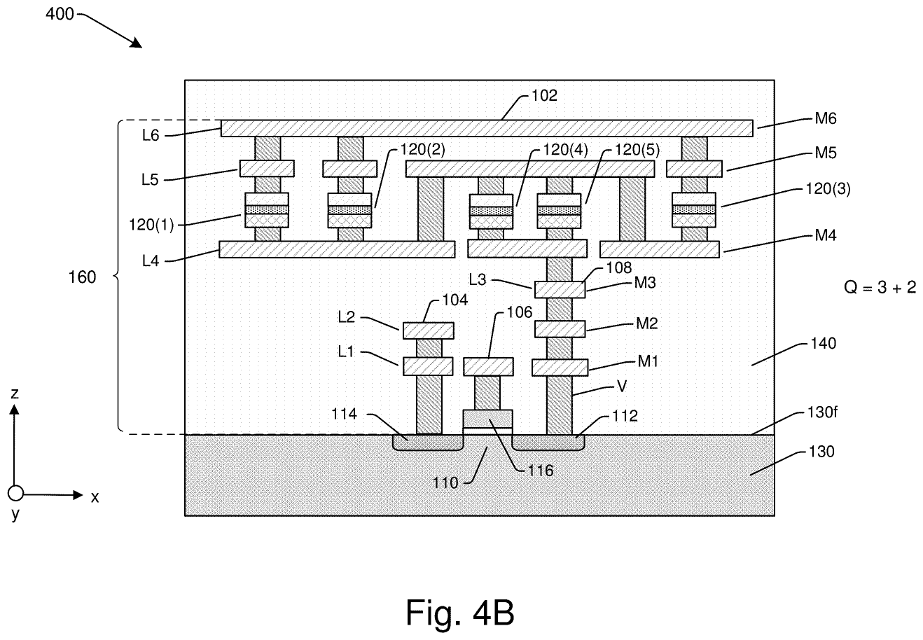

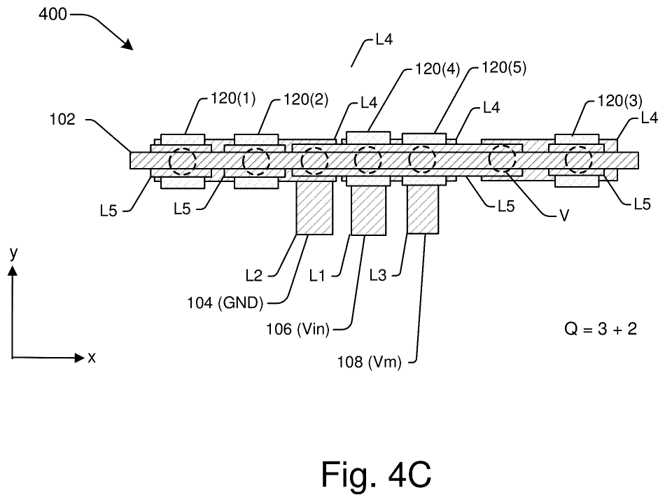

In the second embodiment, the plurality (Q) of MTJs 120 (such as 120(1)-120(Q)) are divided into a first element group 120G(1) and a second element group 120G(2). The first element group 120G(1) includes a first number (n) of MTJs 120 (such as 120(1)-120(n)). The second element group 120G(2) includes a second number (m) of MTJs 120 (such as 120(n+1)-120(Q)). The MTJs 120(1)-120(n) of the first element group 120G(1) are coupled between the first power node 102 and an intermediate node 152 and coupled in parallel to each other when n ≥2 (as shown in FIGS. 3A and 4A). The MTJs 120(n+1)-120(Q) of the second element group 120G(2) are coupled between the intermediate node 152 and the output node Vm and coupled in parallel to each other when m≥2; (as shown in FIG. 4A).

As shown in FIG. 3A, in some embodiments, the configuration of the Gaussian bit circuit 300 is “1T+(2+1) MTJ”. The three MTJs 120(1)-120(3) are divided into a first element group 120G(1) and a second element group 120G(2). The first element group 120G(1) includes a first MTJ 120(1) and a second MTJ 120(2) coupled in parallel to each other between the first power node 102 (for VDD) and the intermediate node 152. The second element group 120G(2) includes a third MTJ 120(3) coupled between the intermediate node 152 and the output node 108 (for providing Vm).

FIG. 4A illustrates a circuit diagram of another exemplary Gaussian bit circuit 400 having a transistor 110 and a plurality of resistance changing elements 120 according to a second embodiment. FIG. 4B illustrates a cross-sectional view of the exemplary Gaussian bit circuit 400 in FIG. 4A according to the second embodiment. FIG. 4C illustrates a layout view of the exemplary Gaussian bit circuit 400 in FIG. 4B according to the second embodiment.

As shown in FIG. 4A, in some embodiments, the configuration of the Gaussian bit circuit 400 is “1T+(3+2) MTJ”. The five MTJs 120(1)-120(5) are divided into a first element group 120G(1) and a second element group 120G(2). The first element group 120G(1) includes a first MTJ 120(1), a second MTJ 120(2), and a third MTJ 120(3) that are coupled in parallel to each other between the first power node 102 (for VDD) and the intermediate node 152. The second element group 120G(2) includes a fourth MTJ 120(4) and a fifth MTJ 120(5) that are coupled in parallel to each other between the intermediate node 152 and the output node 108 (for providing Vm).

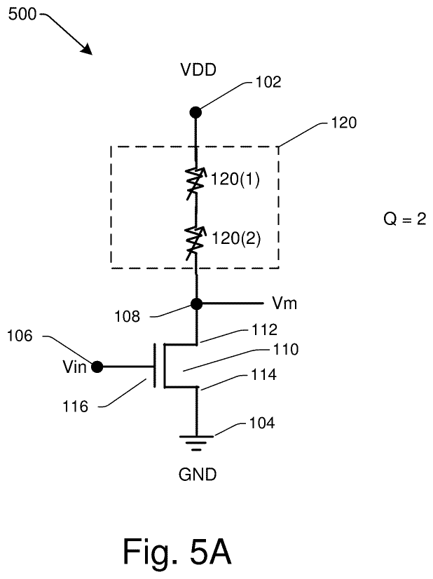

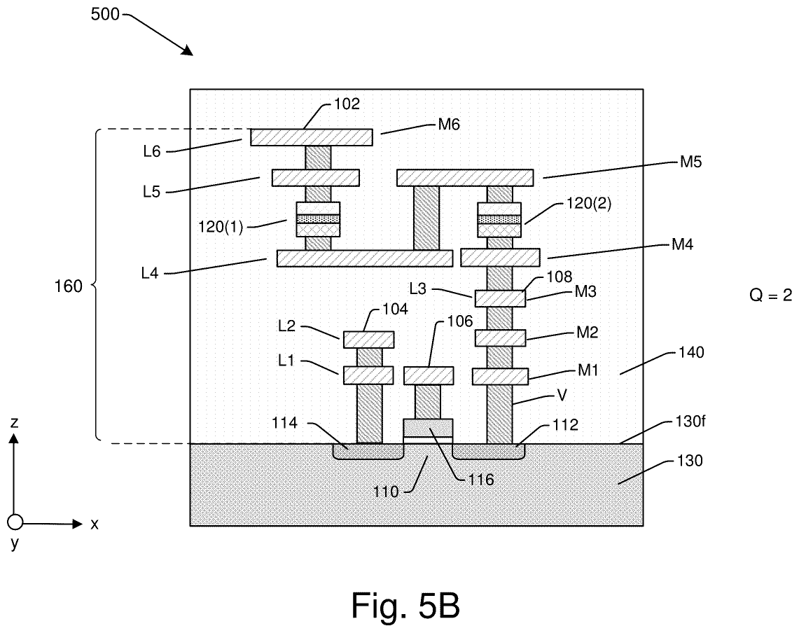

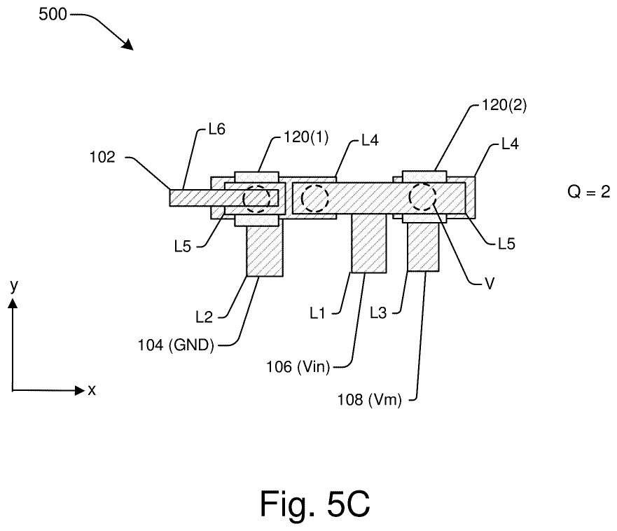

FIG. 5A illustrates a circuit diagram of an exemplary Gaussian bit circuit 500 having a transistor 110 and a plurality of resistance changing elements 120 according to a third embodiment. FIG. 5B illustrates a cross-sectional view of the exemplary Gaussian bit circuit 500 in FIG. 5A according to the third embodiment. FIG. 5C illustrates a layout view of the exemplary Gaussian bit circuit 500 in FIG. 5B according to the third embodiment.

In some embodiments, the Gaussian bit circuit 500 includes a first power node 102 for receiving one of a supply voltage (VDD), a second power node 104 for receiving a reference voltage (GND), an input node 106 for receiving an input signal (Vin), an output node 108 for providing an output signal (Vm), a transistor 110 including a first terminal 112 that is coupled to the output node 108, a second terminal 114 that is coupled to the second power node 104, and a control terminal 116 that is coupled to the input node 106, and a plurality (Q) of MTJs 120(1)-120(Q) that are coupled in series between the first power node 102 and the output node 108. As shown in FIG. 5A, in some embodiments, Q=2, that is a first MTJ 120(1) and a second MTJ 120(2) are coupled in series between the first power node 102 and the output node 108. The exemplary Gaussian bit circuit 100 in FIG. 5A has at least three states. That is, the output (or output signal) Vm has at least three voltage magnitudes when the transistor 110 conducts.

As shown in FIGS. 5B and 5C, in some embodiments, the input node 106 and the output node 108 are arranged in conductive layers that are over the transistor 110 and under the MTJs 120(1) and 120(2), and the output node 108 is arranged in a conductive layer that is over the input node 106. In some embodiments, the MTJs 120(1) and 120(2)) are arranged coplanar as shown in FIG. 5B, while in other embodiments, the MTJs 120(1) and 120(2) are not coplanar (not shown).

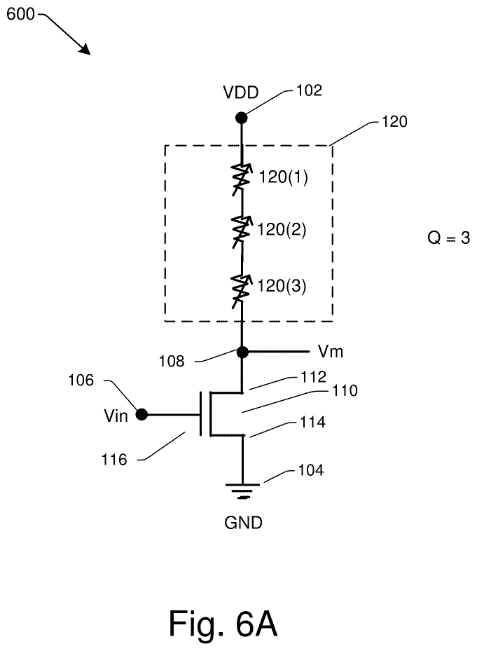

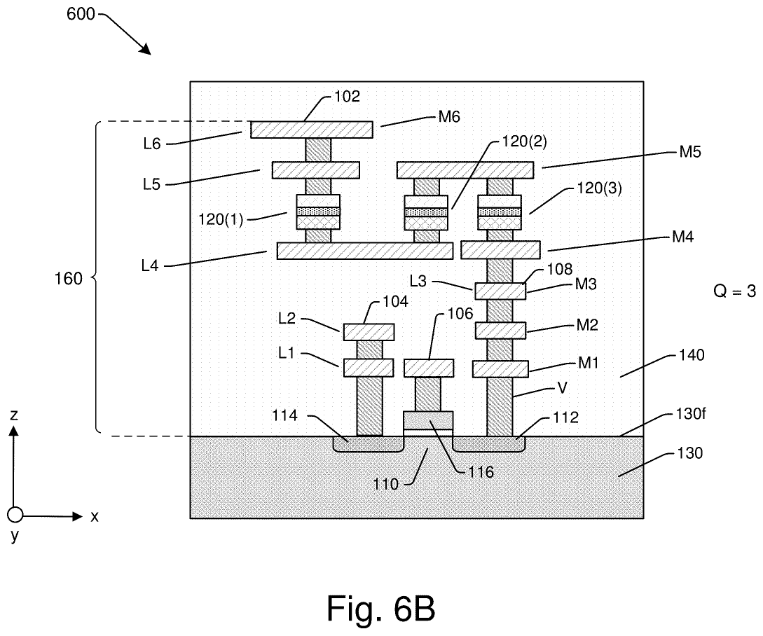

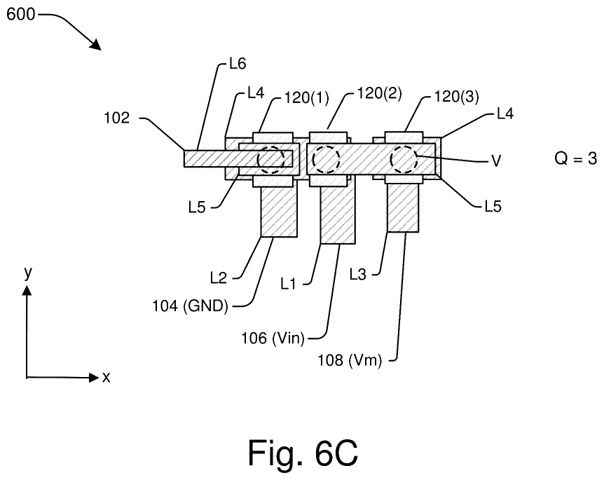

FIG. 6A illustrates a circuit diagram of another exemplary Gaussian bit circuit 600 having a transistor and a plurality of resistance changing elements according to a third embodiment. FIG. 6B illustrates a cross-sectional view of the exemplary Gaussian bit circuit 600 in FIG. 6A according to the third embodiment. FIG. 6C illustrates a layout view of the exemplary Gaussian bit circuit 600 in FIG. 6B according to the third embodiment. The exemplary Gaussian bit circuit 600 in FIG. 6A is similar to the exemplary Gaussian bit circuit 500 in FIG. 5A, except that the exemplary Gaussian bit circuit 600 includes three MTJs 120(1), 120(2), and 120(3) that are coupled in series between the first power node 102 and the output node 108. As shown in FIGS. 6B and 6C, in some embodiments, the input node 106 and the output node 108 are arranged in conductive layers that are over the transistor 110 and under the MTJs 120 (such as120(1)-120(3)), and the output node 108 is arranged in a conductive layer that is over the input node 106.

Although FIG. 5A shows that the number of MTJs 120 coupled in series between the first power node 102 and the output node 108 is two and FIG. 6A shows that the number of MTJs 120 coupled in series between the first power node 102 and the output node 108 is three, the number of MTJs 120 coupled in series between the first power node 102 and the output node 108 can be any integer greater than two according to the third embodiment. In some embodiments, the number of MTJs 120 coupled in series between the first power node 102 and the output node 108 is in a range from 2 to 10.

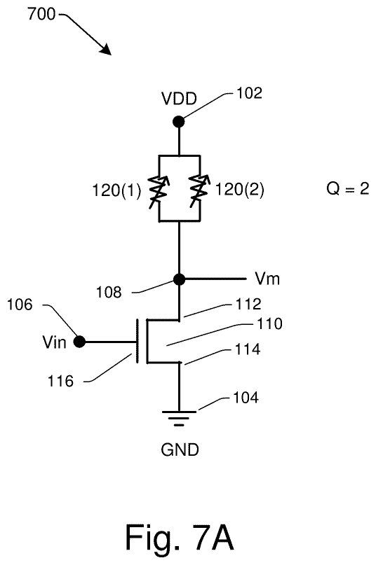

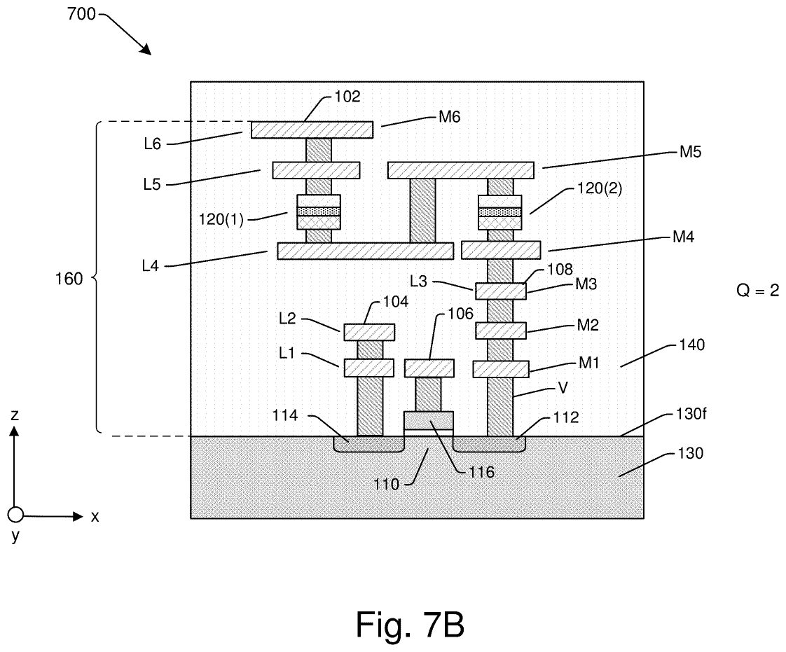

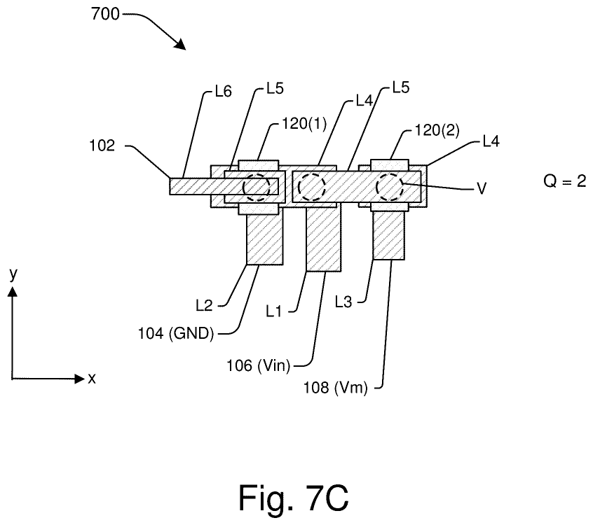

FIG. 7A illustrates a circuit diagram of an exemplary Gaussian bit circuit 700 having a transistor 110 and a plurality of resistance changing elements 120 according to a fourth embodiment. FIG. 7B illustrates a cross-sectional view of the exemplary Gaussian bit circuit 700 in FIG. 7A according to the fourth embodiment. FIG. 7C illustrates a layout view of the exemplary Gaussian bit circuit 700 in FIG. 7B according to the fourth embodiment.

In some embodiments, the exemplary Gaussian bit circuit 700 includes a first power node 102 for receiving one of a supply voltage (VDD), a second power node 104 for receiving a reference voltage (GND), an input node 106 for receiving an input signal (Vin), an output node 108 for providing an output signal (Vm), a transistor 110 including a first terminal 112 that is coupled to the output node 108, a second terminal 114 that is coupled to the second power node 104, and a control terminal 116 that is coupled to the input node 106, and a plurality (Q) of MTJs 120 (120(1)-120(Q)) that are coupled in parallel between the first power node 102 and the output node 108. As shown in FIG. 7A, in some embodiments, Q =2, that is, a first MTJ 120(1) and a second MTJ 120(2) are coupled in parallel between the first power node 102 and the output node 108.

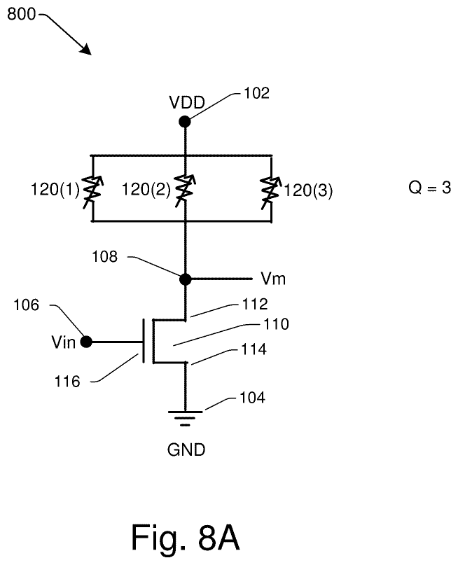

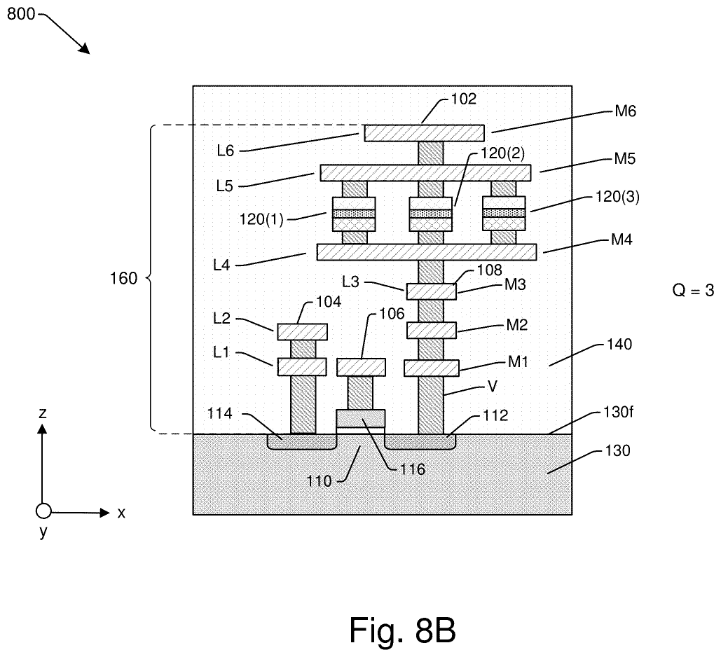

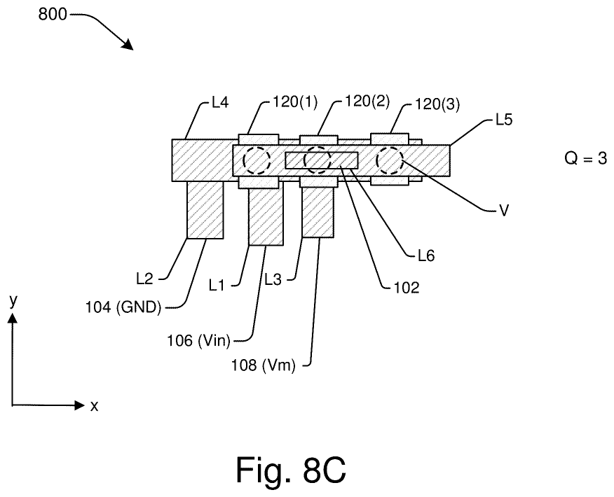

FIG. 8A illustrates a circuit diagram of another exemplary Gaussian bit circuit 800 having a transistor and a plurality of resistance changing elements according to a fourth embodiment. FIG. 8B illustrates a cross-sectional view of the exemplary Gaussian bit circuit 800 in FIG. 8A according to the fourth embodiment. FIG. 8C illustrates a layout view of the exemplary Gaussian bit circuit 800 in FIG. 8B according to the fourth embodiment. The exemplary Gaussian bit circuit 800 in FIG. 8A is similar to the exemplary Gaussian bit circuit 700 in FIG. 7A, except that the exemplary Gaussian bit circuit 800 includes three MTJs 120(1), 120(2), and 120(3) that are coupled in parallel between the first power node 102 and the output node 108. As shown in FIGS. 8B and 8C, in some embodiments, the input node 106 and the output node 108 are arranged in conductive layers that are over the transistor 110 and under the MTJs 120 (such as120(1)-120(3)), and the output node 108 is arranged in a conductive layer that is over the input node 106.

Although FIG. 7A shows that the number of MTJs 120 coupled in parallel between the first power node 102 and the output node 108 is two and FIG. 8A shows that the number of MTJs 120 coupled in parallel between the first power node 102 and the output node 108 is three, the number of MTJs 120 coupled in parallel between the first power node 102 and the output node 108 can be any integer greater than one according to the third embodiment. In some embodiments, the number of MTJs 120 coupled in parallel between the first power node 102 and the output node 108 is in a range from 2 to 10.

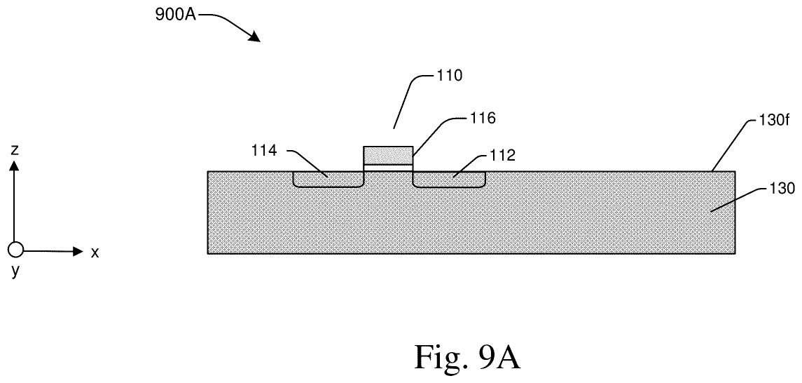

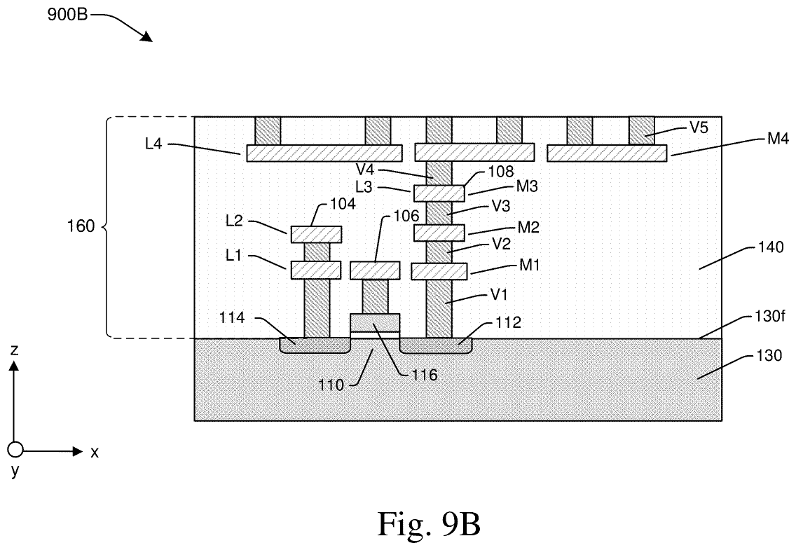

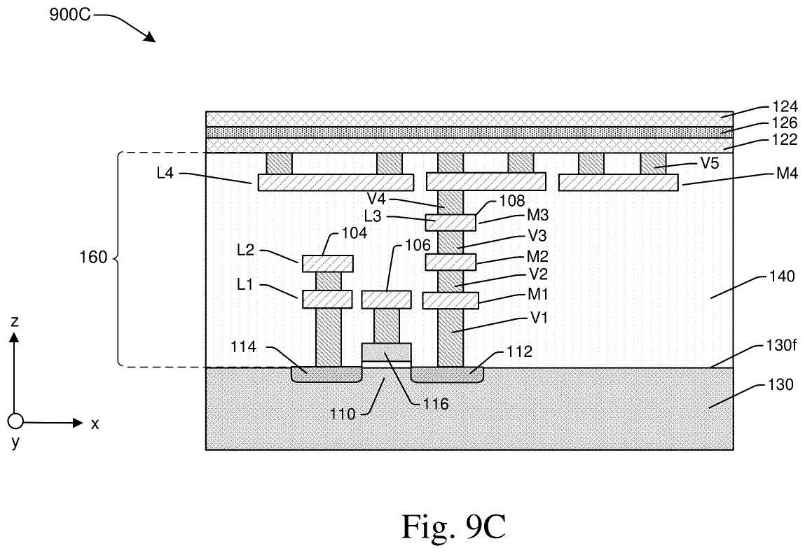

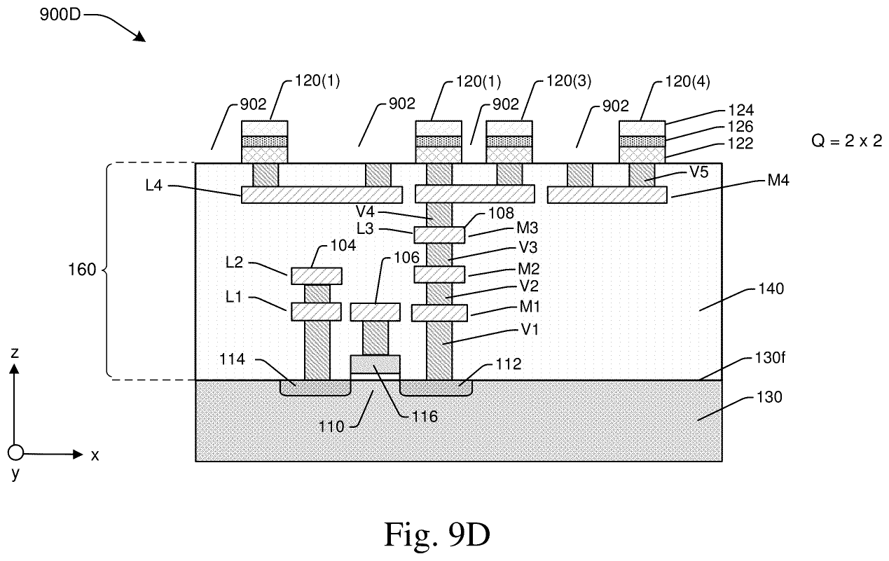

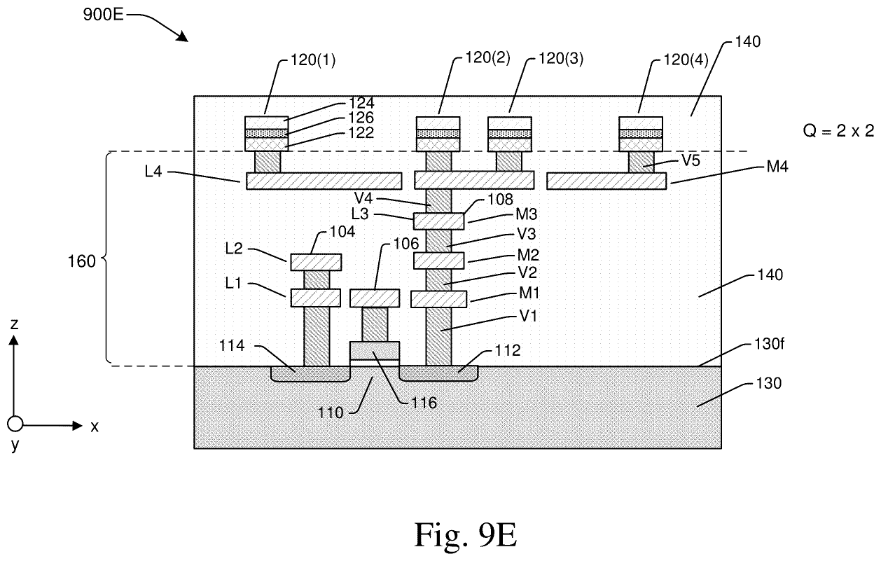

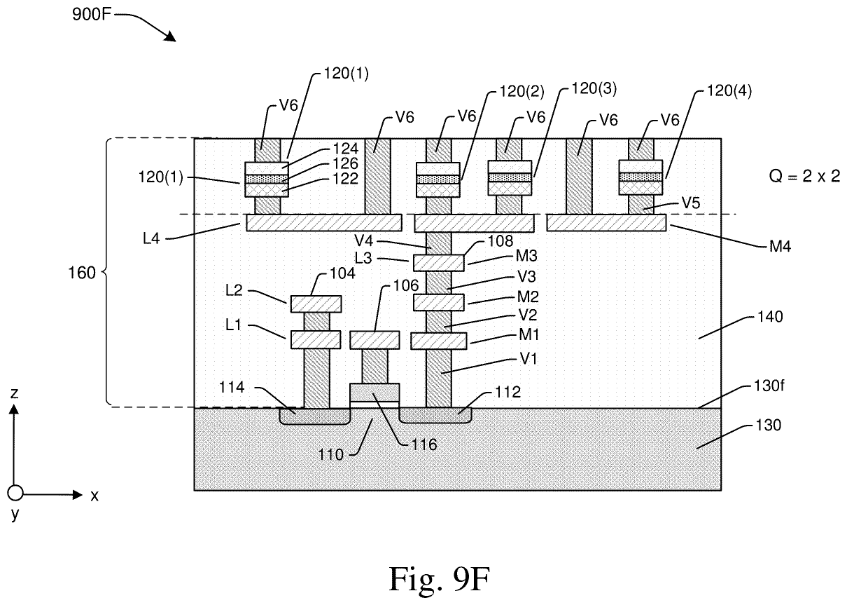

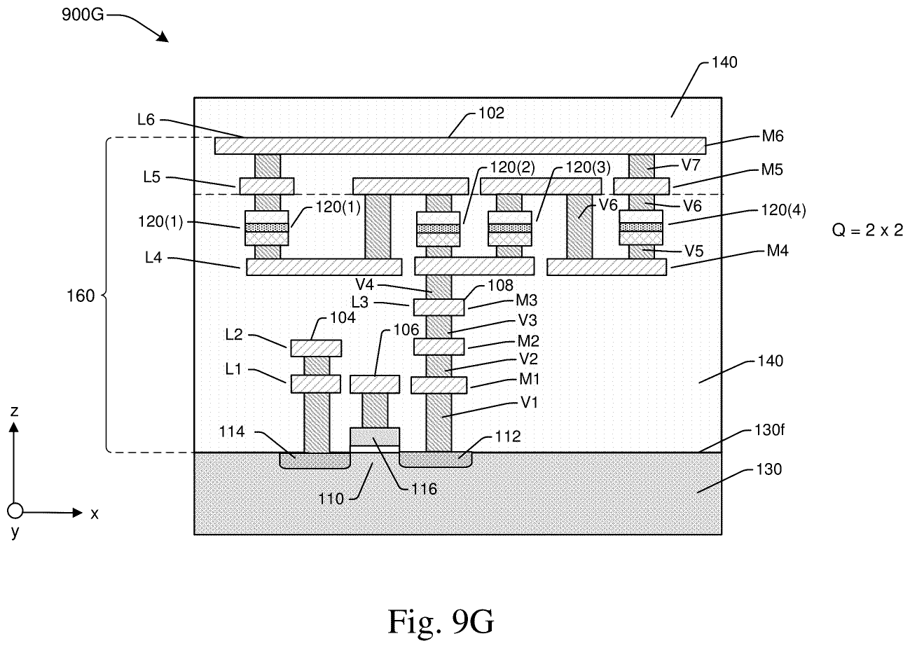

FIGS. 9A-9G are a series of cross-sectional views of intermediate semiconductor structures that illustrate some exemplary steps of a method for manufacturing an exemplary Gaussian bit circuit 100 having a transistor and a plurality of resistance changing elements in FIGS. 1A, 1D and 1E according to some embodiments. Although FIGS. 9A-9G are described in relation to a method, it will be appreciated that the structures disclosed in FIGS. 9A-9G are not limited to such a method, but instead may stand alone as structures independent of the method.

Referring to FIGS. 1A, 1D and 1E, the exemplary Gaussian bit circuit 100 includes a first power node 102 for receiving a supply voltage (VDD), a second power node 104 for receiving a reference voltage (GND), an input node 106 for receiving an input signal (Vin), an output node 108 for providing an output signal (Vm), a transistor 110 including a first terminal 112 coupled to the output node 108, a second terminal 114 coupled to the second power node 104, and a control terminal 116 coupled to the input node 106, and a plurality (e.g., four) of MTJs 120 (such as 120(1)-120(4)) coupled between the first power node 102 and the output node 108 in a combination of series and parallel. MTJs 120(1) and 120(2) are coupled in series and form a first element group 120G(1), MTJs 120(3) and 120(4) are coupled in series and form a second element group 120G(2), and the first element group 120G(1) and the second element group 120G(2) are coupled in parallel.

As shown in cross-sectional view 900A of FIG. 9A, in some embodiments, a transistor 110 including a first source/drain terminal 112, a second source/drain terminal 114, and a gate terminal 116 is formed along a frontside 130f of a semiconductor substrate 130.

As shown in cross-sectional view 900B of FIG. 9B, in some embodiments, a dielectric layer 140 is formed over the frontside 130f of a semiconductor substrate 130, and a conductive interconnect structure 160 is formed in the dielectric layer 140. In some embodiments, the conductive interconnect structure 160 includes a plurality of conductive lines L (such as L1-L6) respectively arranged in a plurality of conductive interconnect layers (such as M1-M6), and a plurality of conductive vias V selectively coupled to some of the plurality of conductive lines L.

In some embodiments, an input node 106 configured to receive an input signal (Vin) is formed in a first conductive layer (such as M1) of a plurality of conductive layers M (such as M1-M6), and is coupled to the control terminal 116 of transistor 110 by at least a portion of the conductive interconnect structure 160. In some embodiments, a second power node 104 is formed in a second conductive layer (such as M2) of the plurality of conductive layers M (such as M1-M6), and is coupled to the second terminal 114 of the transistor 110 by at least a portion of the conductive interconnect structure 160. In some embodiments, an output node 108 configured to provide an output signal (Vm) is formed in a third conductive layer (such as M3) of the plurality of conductive layers M (such as M1-M6).

As shown in cross-sectional view 900C of FIG. 9C, in some embodiments, a pinned magnetic layer 122 is formed over a top surface of the dielectric layer 140, a tunnel barrier layer 126 is formed over the pinned magnetic layer 122, and a free magnetic layer 124 is formed over the pinned magnetic layer 122 by employing for example deposition processes (such as CVD, PVD, and the like). The material of the pinned magnetic layer 122 has a fixed magnetization direction. The material of the free magnetic layer 124 has a magnetization direction that can switch. The material of the tunnel barrier layer 126 vertically isolates the pinned magnetic layer 122 and the free magnetic layer 124. In some embodiments, the material of the pinned magnetic layer 122 includes Cobalt Iron Boron (CoFeB) or Cobalt Iron (CoFe). In some embodiments, the material of the free magnetic layer 124 includes CoFeB or Iron Nickel (NiFe) alloys. In some embodiments, the material of the tunnel barrier layer 126 includes Magnesium Oxide (MgO) or Aluminum Oxide (Al₂O₃).

As shown in cross-sectional view 900D of FIG. 9D, in some embodiments, openings (or recesses) 902 are formed vertically through the free magnetic layer 124, the tunnel barrier layer 126, and the pinned magnetic layer 122 in some areas by employing for example a lithography process followed by an etching process, while retaining the free magnetic layer 124, the tunnel barrier layer 126, and the pinned magnetic layer 122 in other areas. As such, a plurality of MTJs 120 (such as 120(1)-120(4)) are formed, each MTJ 120 (such as 120(4)) includes a pinned magnetic layer 122, a free magnetic layer 124, and a tunnel barrier layer 126 vertically between the pinned magnetic layer 122 and the free magnetic layer 124 to separate them from each other.

As shown in cross-sectional view 900E of FIG. 9E, in some embodiments, an additional layer of the dielectric layer 140 is formed to fill the openings 902 (in FIG. 9D) and to overlay the top surfaces of the MTJs 120 (such as 120(1)-120(4)) by employing for example a deposition process (such as CVD, PVD, and the like).

As shown in cross-sectional view 900F of FIG. 9F, in some embodiments, a plurality of vias V (such as V6) are formed by employing for example a lithography process followed by an etching process and a deposition process (such as CVD, PVD, and the like). In some embodiments, some of the vias V6 are coupled to the free magnetic layers 124 of the MTJs 120 (such as 120(1)-120(4)), and others of the vias V6 are coupled to some of the conductive lines L (such as L4) of the conductive interconnect structure 160.

As shown in cross-sectional view 900G of FIG. 9G, in some embodiments, an additional dielectric layer 140 is formed over the vias V6 and the existing dielectric layer 140, and additional conductive lines (such as conductive lines L5 in M5, and a conductive line L6 in M6) and additional conductive vias (such as V7) of the conductive interconnect structure 160 are formed within the additional dielectric layer 140 by employing for example processes of lithography, etching, and deposition (such as CVD, PVD, and the like). In some embodiments, a conductive line L6 in M6 is formed to function as a first power node 102 for receiving a supply voltage (VDD). MTJs 120(1) and 120(2) are coupled in series and form a first element group 120G(1), MTJs 120(3) and 120(4) are coupled in series and form a second element group 120G(2), and the first element group 120G(1) and the second element group 120G(2) are coupled in parallel.

In this way, the exemplary Gaussian bit circuit 100 including multiple MTJs 120 and predominantly one transistor 110, one input node 106, and one output node 108 as shown in, e.g., FIG. 1D is formed, which occupies a smaller area and has simplified metal line routing for the input node and the output node, thereby advantageously enhancing integration efficiency and scalability.

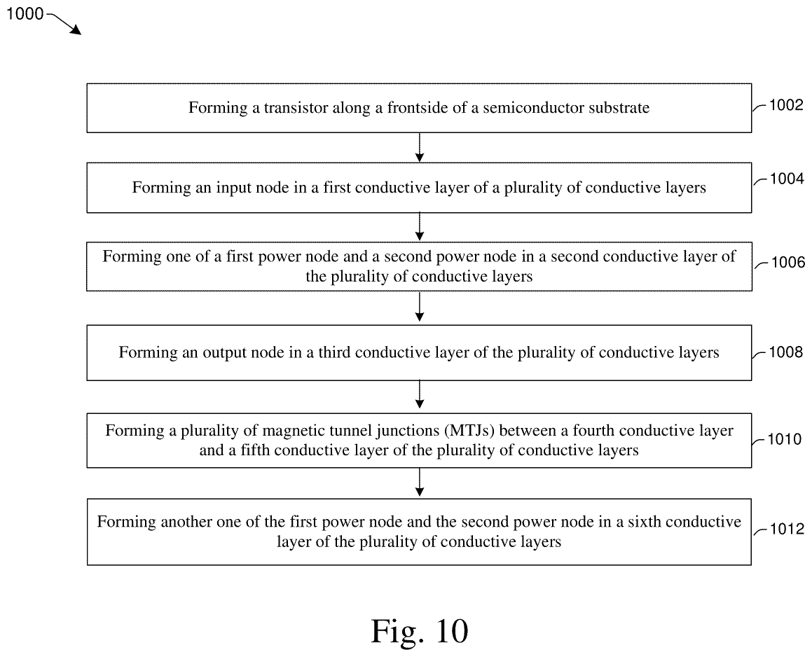

FIG. 10 illustrates a flow diagram of a method 1000 for manufacturing an exemplary Gaussian bit circuit 100 having a transistor 110 and a plurality of resistance changing elements 120 as shown in FIGS. 1A, 1D and 1E according to some embodiments. While method 1000 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

As shown in FIGS. 1A and 1D, the exemplary Gaussian bit circuit 100 includes a first power node 102 for receiving a supply voltage (VDD), a second power node 104 for receiving a reference voltage (GND), an input node 106 for receiving an input signal (Vin), an output node 108 for providing an output signal (Vm), a transistor 110 including a first terminal 112 coupled to the output node 108, a second terminal 114 coupled to the second power node 104, and a control terminal 116 coupled to the input node 106, and a plurality (Q) of MTJs 120 (120(1) 120(Q)) coupled between the first power node 102 and the output node 108 in a combination of series and parallel (such as Q=4 in FIG. 1A).

As shown, e.g., in FIG. 1D, a conductive interconnect structure 160 is formed in the dielectric layer 140, and includes a plurality of conductive lines L (such as L1-L6, etc.) respectively arranged in a plurality of conductive interconnect layers (such as M1-M6, etc.), and a plurality of conductive vias V selectively coupled to the plurality of conductive lines L for selectively connecting the elements and nodes. In some embodiments, the conductive interconnect structure 160 can be made of a conductive material such as Aluminum (Al), Tungsten (W), cobalt (Co), ruthenium (Ru), and Copper (Cu), ), or the like. The interconnect structure 160 may further include one or more titanium (Ti)-or tantalum (Ta)-based liner or barrier layers, a cobalt (Co) capping layer, or a cobalt-based barrier layer.

At act 1002, as shown in FIGS. 9A and 10, in some embodiments, a transistor 110 including a first source/drain terminal 112, a second source/drain terminal 114, and a gate terminal 116 is formed along a frontside 130f of a semiconductor substrate 130 (referring to FIG. 10 and FIG. 1D). In some embodiments, as shown in FIG. 9B, a dielectric layer 140 is formed over the frontside 130f of a semiconductor substrate 130, and a plurality of conductive vias V are formed in the dielectric layer 140.

In some embodiments, the semiconductor substrate 130 may be any type of semiconductor substrate (such as silicon, SiGe, SOI, etc.), such as a semiconductor wafer, as well as any other type of semiconductor and/or epitaxial layers, associated therewith. In some embodiments, the dielectric layer 140 may include a low-k material such as silicon dioxide (SiO₂) with k=3.9, and other low-k materials with k values less than the k value (3.9) of SiO₂, such as Fluorine-doped silicon dioxide (SiOF) (k is about 3.0-4.0), carbon doped silicon dioxide (SiCOH), phosphosilicate glass (PSG), organosilicate glass (OSG) (k is about 2.5-3.0), porous silicon dioxide (k is about 1.3-2.5), porous organosilicate glass (k is about 2.5-3.0), polymetric materials (like polyimide, parylene, PTFE, with k is about 2.0-3.1), air gaps (k is about 1.0), borophosphosilicate glass (BPSG), borosilicate glass (BSG), fluorosilicate glass (FSG), undoped silicate glass (USG), and/or the like.

At act 1004, as shown in FIGS. 9B and 10, in some embodiments, an input node 106 configured to receive an input signal (Vin) is formed in a first conductive layer (such as M1) of a plurality of conductive layers (such as M1-M6) (referring to FIG. 10 and FIG. 1D). The input node 106 is coupled to the control terminal 116 by at least a portion of the conductive interconnect structure 160.

At act 1006, as shown in FIGS. 9B and 10, in some embodiments, one of a first power node 102 and a second power node 104 is formed in a second conductive layer (such as M2) of the plurality of conductive layers (such as M1-M6) (referring to FIG. 10 and FIG. 1D). In some embodiments, the second conductive layer (such as M2) is formed over the first conductive layer (such as M1). In some embodiments, the second power node 104 is formed in the second conductive layer (such as M2) of the plurality of conductive layers (such as M1-M6), and is coupled to the second terminal 114 by at least a portion of the conductive interconnect structure 160 (in FIG. 1D).

At act 1008, as shown in FIGS. 9B and 10, in some embodiments, an output node 108 configured to provide an output signal (Vm) is formed in a third conductive layer (such as M3) of the plurality of conductive layers (such as M1-M6) (referring to FIG. 10 and FIG. 1D). In some embodiments, the third conductive layer (such as M3) is formed over the second conductive layer (such as M2).

At act 1010, as shown in FIGS. 9C-9E and 10, in some embodiments, a plurality (Q) of MTJs 120 (such as 120(1)-120(Q)) are formed between a fourth conductive layer (such as M4) and a fifth conductive layer (such as M5) of the plurality of conductive layers (such as M1-M6). In some embodiments, the fourth conductive layer (such as M4) is formed over the third conductive layer (such as M3), and the fifth conductive layer (such as M5) is formed over the fourth conductive layer (such as M4).

In some embodiments, the plurality (Q) of MTJs 120 (such as 120(1)-120(Q)) are divided into a number (n) of element groups 120G (such as 120G(1)-120G(n)) that are coupled in parallel between the first power node 102 and the output node 108, and each element group 120G (such as 120G(1)) includes a number (m) of resistance changing elements 120 (such as 120(1)-120(m)) coupled in series, and thus Q=n×m. In some embodiments, as shown in FIG. 9G, n=m=2, and such a configuration can be referred to as a “1T+(n×n) MTJ” configuration.

As shown in FIG. 9G, the four MTJs 120(1)-120(4)) are divided into two element groups 120G(1) and 120G(2) that are coupled in parallel between the first power node 102 and the output node 108 by at least a portion of the conductive interconnect structure 160, element group 120G(1) includes MTJ 120(1) and MTJ 120(2) that are coupled in series by at least a portion of the conductive interconnect structure 160, and element group 120G(2) includes MTJ 120(3) and MTJ 120(4) that are coupled in series by at least a portion of the conductive interconnect structure 160.

At act 1012, as shown in FIGS. 9G and 10, in some embodiments, another one of the first power node 102 and the second power node 104 is formed in a sixth conductive layer (such as M6) of the plurality of conductive layers (such as M1-M6) (referring to, e.g., FIG. 10 and FIG. 1D). In some embodiments, the sixth conductive layer (such as M6) is formed over the fifth conductive layer (such as M5). In some embodiments, the first power node 102 is formed in the sixth conductive layer (such as M6) of the plurality of conductive layers (such as M1-M6) (referring to such as FIG. 1D).

As such, the Gaussian bit circuit 100 in such as FIG. 1D is formed, which predominantly requires one transistor 110, one input node 106, and one output node 108, thus occupies a smaller area, and has simplified metal line routing for the input and output signals, thereby advantageously enhancing integration efficiency and scalability.

Accordingly, in some embodiments, an integrated circuit is provided. The integrated circuit includes a first power node for receiving one of a supply voltage and a reference voltage; a second power node for receiving another of the supply voltage and the reference voltage; an input node for receiving an input signal; an output node for providing an output signal; a transistor including a first terminal coupled to the output node, a second terminal coupled to the second power node, and a control terminal coupled to the input node; and a memory cell including a plurality of resistance changing elements coupled between the first power node and the output node. The memory cell is configured to have a number of discrete data states greater than a number of resistance changing elements in the plurality of resistance changing elements. In some embodiments, the plurality of resistance changing elements are coupled between the first power node and the output node in parallel. In some embodiments, the plurality of resistance changing elements are coupled between the first power node and the output node in series. In some embodiments, each of the plurality of resistance changing elements comprises a magnetic tunnel junction (MTJ). In some embodiments, each of the plurality of resistance changing elements is configured to have a low-resistance state (LRS) and high-resistance state (HRS). In some embodiments, the memory cell is configured to have a first data state when each of the plurality of resistance changing elements is in the LRS; the memory cell is configured to have a second data state when a single resistance changing element in the plurality of resistance changing elements is in the HRS and remaining resistance changing elements in the plurality of resistance changing elements are each in the LRS; and the memory cell is configured to have a third data state when each of the plurality of resistance changing elements is in the HRS. In some embodiments, the plurality of resistance changing elements are divided and arranged into a number of element groups that are coupled in parallel between the first power node and the output node, and each element group comprises a number of resistance changing elements coupled in series. In some embodiments, the number of element groups is equal to the number of resistance changing elements in each element group. In some embodiments, the number of element groups is different from the number of resistance changing elements in each element group. In some embodiments, the integrated circuit further includes a semiconductor substrate having a first surface, wherein the transistor is arranged along the first surface of the semiconductor substrate; and a dielectric structure over the semiconductor substrate, wherein the plurality of resistance changing elements are arranged in the dielectric structure and overlie the transistor. In some embodiments, the integrated circuit further includes a conductive interconnect structure in the dielectric structure, the conductive interconnect structure includes a plurality of conductive interconnect layers vertically stacked over one another, and the plurality of resistance changing elements are coplanar and spaced vertically between two adjacent conductive interconnect layers in the plurality of conductive interconnect layers.

In other embodiments, an integrated circuit is provided. The integrated circuit includes a first power node for receiving one of a supply voltage and a reference voltage; a second power node for receiving another of the supply voltage and the reference voltage; an input node for receiving an input signal; an output node for providing an output signal; a transistor including a first terminal coupled to the output node, a second terminal coupled to the second power node, and a control terminal coupled to the input node; and a plurality of resistance changing elements coupled between the first power node and the output node, wherein the plurality of resistance changing elements are divided into a first element group and a second element group coupled in series, wherein the first element group comprises a number of first resistance changing elements coupled in parallel to each other, and wherein the second element group comprises one or more second resistance changing elements. In some embodiments, the first element group is coupled between the first power node and an intermediate node, and the second element group is coupled between the intermediate node and the output node. In some embodiments, the second element group comprises a number of second resistance changing elements coupled in parallel. In some embodiments, the number of the first resistance changing elements is greater than the number of the second resistance changing elements. In some embodiments, the input node and the output node are arranged over the transistor and under the plurality of resistance changing elements, and the output node is arranged over the input node.

In yet other embodiments, a method of manufacturing an integrated circuit is provided. The method includes forming a transistor along a first surface of a semiconductor substrate and comprising a first terminal; forming a first plurality of conductive interconnects over the first surface of the semiconductor substrate, wherein the first plurality of conductive interconnects comprises a first conductive line electrically coupled to the first terminal of the transistor; forming a plurality of resistance changing elements over the first plurality of conductive interconnects; and forming a second plurality of conductive interconnects over the plurality of resistance changing elements. The second plurality of conductive interconnects comprises a second conductive line. The plurality of resistance changing elements are coupled between the first conductive line and the second conductive line in series, in parallel, or in a combination of series and parallel. In some embodiments, bottom surfaces of the plurality of resistance changing elements are aligned with one another. In some embodiments, the first conductive line is or is coupled to an output node and the second conductive line is or is coupled to a first power node, the first plurality of conductive interconnects further comprises a third conductive line electrically coupled to a second terminal of the transistor, the third conductive line is or is coupled to a second power node, the first power node is configured to receive one of a supply voltage and a reference voltage, and the second power node is configured to receive another of the supply voltage and the reference voltage. In some embodiments, the plurality of resistance changing elements includes a first element group and a second element group coupled in parallel, the first element group and the second element group each include at least two resistance changing elements coupled in series.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a transistor arranged along a semiconductor substrate;
an interconnect structure overlying the transistor, wherein the interconnect structure comprises a plurality of conductive lines respectively arranged in a plurality of conductive interconnect layers, and a plurality of conductive vias; and
a memory cell overlying the transistor and coupled to the transistor by the interconnect structure, wherein the memory cell comprises a plurality of resistance changing elements that are coupled to one another by the interconnect structure, and arranged vertically between a first conductive interconnect layer and a second conductive interconnect layer of the plurality of conductive interconnect layers, the second conductive interconnect layer overlying and being adjacent to the first conductive interconnect layer.

2. The integrated circuit of claim 1, wherein top surfaces of the plurality of resistance changing elements are coplanar.

3. The integrated circuit of claim 1, wherein the plurality of resistance changing elements are divided and arranged into a number of element groups that are coupled in parallel, and wherein each element group comprises a number of resistance changing elements coupled in series.

4. The integrated circuit of claim 3, wherein the number of element groups is equal to the number of resistance changing elements in each element group.

5. The integrated circuit of claim 3, wherein the number of element groups is different from the number of resistance changing elements in each element group.

6. The integrated circuit of claim 1, wherein each of the plurality of resistance changing elements comprises a magnetic tunnel junction (MTJ).

7. The integrated circuit of claim 1, wherein each of the plurality of resistance changing elements is configured to have a low-resistance state and a high-resistance state.

8. The integrated circuit of claim 7, wherein the memory cell is configured to have a first data state when each of the plurality of resistance changing elements is in the low-resistance state;
wherein the memory cell is configured to have a second data state when a single resistance changing element in the plurality of resistance changing elements is in the high-resistance state and remaining resistance changing elements in the plurality of resistance changing elements are each in the low-resistance state; and
wherein the memory cell is configured to have a third data state when each of the plurality of resistance changing elements is in the high-resistance state.

9. The integrated circuit of claim 1, wherein the plurality of resistance changing elements are coupled in parallel.

10. The integrated circuit of claim 1, wherein the plurality of resistance changing elements are coupled in series.

11. The integrated circuit of claim 1, wherein the plurality of resistance changing elements are coupled in a combination of series and parallel configuration.

12. An integrated circuit, comprising:
a transistor arranged along a semiconductor substrate, and comprising a first source/drain terminal, a second source/drain terminal, and a control terminal;
an interconnect structure overlying the transistor, and comprising a plurality of conductive lines respectively arranged in a plurality of conductive interconnect layers, and a plurality of conductive vias; and
a plurality of resistance changing elements coupled to the transistor by the interconnect structure and arranged vertically between a first conductive interconnect layer and a second conductive interconnect layer of the plurality of conductive interconnect layers, the second conductive interconnect layer being over and adjacent to the first conductive interconnect layer, wherein the plurality of resistance changing elements are divided into a first element group and a second element group coupled in series, wherein the first element group comprises a number of first resistance changing elements coupled in parallel to each other, and wherein the second element group comprises one or more second resistance changing elements.

13. The integrated circuit of claim 12, wherein the second element group comprises a number of second resistance changing elements coupled in parallel.

14. The integrated circuit of claim 13, wherein the number of the first resistance changing elements is greater than the number of the second resistance changing elements.

15. The integrated circuit of claim 12, wherein the first element group is coupled between a power node and an intermediate node, and wherein the second element group is coupled between an intermediate node and an output node.

16. The integrated circuit of claim 12, further comprising:
a first power node for receiving one of a supply voltage and a reference voltage;
a second power node for receiving another of the supply voltage and the reference voltage;
an input node for receiving an input signal; and
an output node for providing an output signal,
wherein the first power node overlies the plurality of resistance changing elements, and
wherein the second power node, the input node and the output node overlie the transistor and underlie the plurality of resistance changing elements.

17. A method of manufacturing an integrated circuit, comprising:
forming a transistor along a first surface of a semiconductor substrate and comprising a first terminal;
forming a first plurality of conductive interconnects over the first surface of the semiconductor substrate, wherein the first plurality of conductive interconnects comprises a first conductive line electrically coupled to the first terminal of the transistor;
forming a plurality of resistance changing elements over the first plurality of conductive interconnects; and
forming a second plurality of conductive interconnects over the plurality of resistance changing elements, wherein the second plurality of conductive interconnects comprises a second conductive line,
wherein the plurality of resistance changing elements are coupled between the first conductive line and the second conductive line in series, in parallel, or in a combination of series and parallel.

18. The method of claim 17, wherein bottom surfaces of the plurality of resistance changing elements are aligned with one another.

19. The method of claim 17, wherein the first conductive line is or is coupled to an output node and the second conductive line is or is coupled to a first power node, wherein the first plurality of conductive interconnects further comprises a third conductive line electrically coupled to a second terminal of the transistor, wherein the third conductive line is or is coupled to a second power node, wherein the first power node is configured to receive one of a supply voltage and a reference voltage, wherein the second power node is configured to receive another of the supply voltage and the reference voltage.

20. The method of claim 17, wherein the plurality of resistance changing elements comprises a first element group and a second element group coupled in parallel, wherein the first element group and the second element group each comprise at least two resistance changing elements coupled in series.
